(19) United States
(12) Patent Application Publication
(10) Pub. No.: US 2010/0073205 A1
(43) Pub. Date: Mar. 25, 2010

(54) PORTABLE ELECTRONIC DEVICE

(75) Inventor: YUN-LONG SIE, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: Chi Mei Communication System, Inc., Tu-Cheng City (TW)

(21) Appl. No.: 12/341,928

(22) Filed: Dec. 22, 2008

(30) Foreign Application Priority Data
Sep. 24, 2008 (CN) 200810304630.2

(51) Int. Cl. G06F 3/02; H03K 17/94

(52) U.S. Cl. 341/31; 345/169

(57) ABSTRACT

A portable electronic device is provided. The portable electronic device includes a central processing unit, a projecting module electronically connected to the central processing unit, a virtual keypad projection module configured to project a virtual keypad on a surface, an infrared radiation generator configured to irradiate infrared light generally parallel with the virtual keypad and an infrared sensor module configured to receive infrared light reflected by fingers of a user pressing the virtual keypad and generate corresponding signals and then send the signals to the central processing unit for the central processing unit to produce commands corresponding to the pressed virtual keypads.

### BACKGROUND

1. Technical Field

The present disclosure relates to portable electronic devices and, particularly, to a portable electronic device which can output information (e.g., images) using projection.

2. Description of Related Art

Portable electronic devices (e.g., mobile phones) are becoming smaller, thinner and more multi-functional.

When requiring larger viewing areas, portable electronic devices may be provided with projection assemblies, and information can be projected by the projection assemblies onto projection screens.

However, the projection assemblies may shake when users manually input information into the portable electronic devices using the keys of the portable electronic devices. Therefore, the images projected on the projection screen may become blurry when the electronic devices are projecting images while users input information using the keys.

Therefore, there is room for improvement within the art.

### BRIEF DESCRIPTION OF THE DRAWINGS

Many aspects of a portable electronic device can be better understood with reference to the following drawings. The drawings are not necessarily drawn to scale, the emphasis instead being placed upon clearly illustrating the principles of the present portable electronic device. Moreover, in the drawings like reference numerals designate corresponding sections throughout the several views.

FIG. 1 is a schematic block diagram of a portable electronic device, in accordance with an exemplary embodiment.

FIG. 2 is a schematic view of a portable electronic device in use show in FIG. 1.

### DETAILED DESCRIPTION OF EXEMPLARY EMBODIMENT

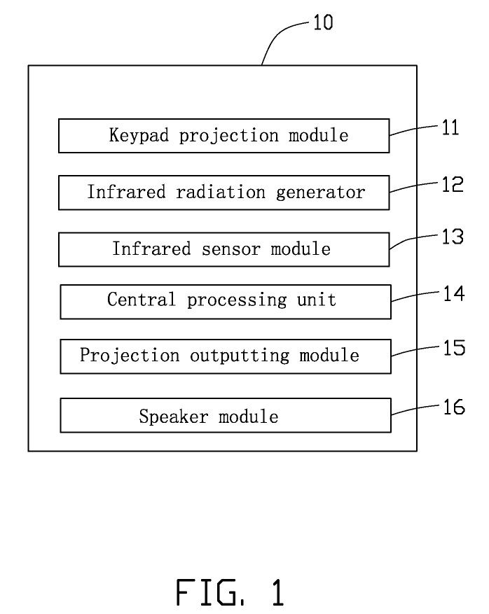

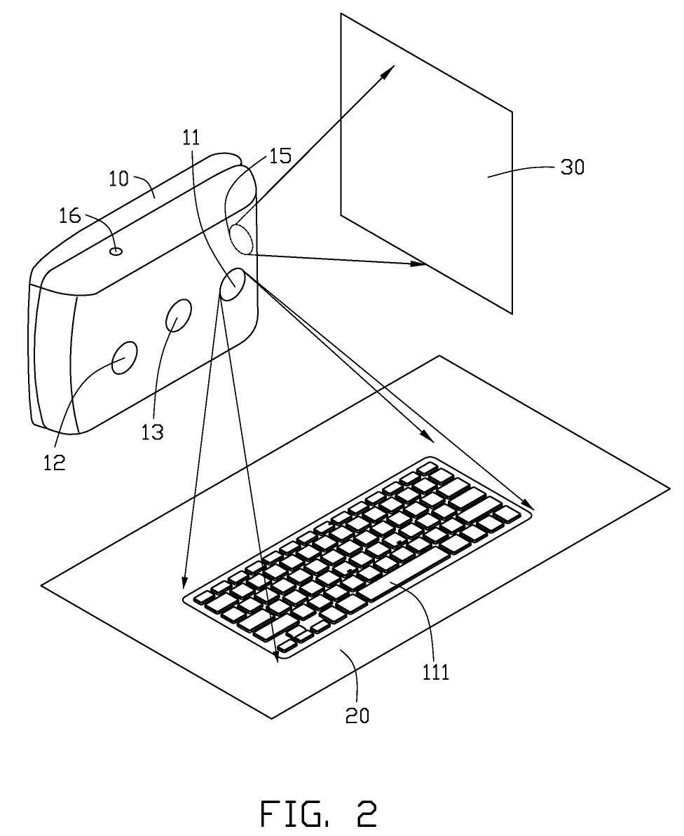

FIGS. 1 and 2 show an exemplary portable electronic device 10. The portable electronic device 10 includes a virtual keypad projection module 11, an infrared radiation generator 12, an infrared sensor module 13, a central processing unit (CPU) 14, a projecting module 15, and a speaker module 16. The infrared sensor module 13, the projecting module 15, and the speaker module 16 are electronically connected to the CPU 14.

The virtual keypad projection module 11 projects a virtual keypad 111 (e.g. image of a keypad) on an outside surface 20 (e.g., a surface of a desk or a wall) using holographic imaging.

The infrared radiation generator 12 radiates infrared light substantially parallel with and substantially close to the virtual keypad 111 on the outside surface 20.

The infrared sensor module 13 receives infrared light reflected by, e.g., a user's fingers touching the virtual keypad 111, and generates electric signals corresponding to the virtual keys touched by the user. The infrared sensor module 13 transforms the electric signals into digital signals, and transmits the digital signals to the CPU 14.

The CPU 14 receives the digital signals transmitted from the infrared sensor module 13 and transforms them into commands, such as display commands and audio commands. The CPU 14 transmits display commands to the projecting module 15. The CPU 14 transmits audio commands to the speaker module 16.

The projecting module 15 receives display commands and displays information on another planar surface 30 of a desk or wall corresponding to the display commands. The speaker module 16 receives audio commands and play audio files corresponding to the audio commands.

In use, the virtual keypad projection module 11 projects a virtual keypad 111 on a planar surface 20 of a desk or wall. The infrared radiation generator 12 evenly radiates the virtual keypad 111 with infrared light. Once a user touches a key of the virtual keypad 111, the infrared sensor module 13 receives infrared light reflected by the finger of the user and identifies the key assignment associated with the touched key. The infrared sensor module 13 produces an electric signal corresponding to the key assignment and transforms the electric signal into a digital signal. The infrared sensor module 13 transmits the digital signal to the CPU 14. Then the CPU 14 transforms the digital signal into a display command and/or audio command which are respectively transmitted to the projecting module 15 to display and the speaker module 16 to play. Therefore, users can input information into the electronic device 10 without touching the physical keypad, thus avoiding shaking the device 10 and ruining the clarity of the projected image on the planar surface 30 of a desk or wall.

It is to be understood, however, that even through numerous characteristics and advantages of the present invention have been set forth in the foregoing description, together with details of the structure and function of the invention, the disclosure is illustrative only, and changes may be made in detail, especially in matters of shape, size, and arrangement of sections within the principles of the invention to the full extent indicated by the broad general meaning of the terms, in which the appended claims are expressed.

What is claimed is:

1. A portable electronic device, comprising:
a central processing unit;
a projecting module electronically connected to the central processing unit;
a virtual keypad projection module configured to project a virtual keypad on a surface;
an infrared radiation generator configured to irradiate infrared light generally parallel with the virtual keypad; and
an infrared sensor module configured to receive infrared light reflected by fingers of a user pressing the virtual keypad and generate corresponding signals and then send the signals to the central processing unit for the central processing unit to produce commands corresponding to the pressed virtual keypads; whereby
data may be entered into the portable electronic device without effecting the clarity of the image projected by the projecting module.

2. The portable electronic device as claimed in claim 1, wherein the signals are electric signals, the infrared sensor module is further configured for changing the electric signals into digital signals, and transmitting the digital signals to the central processing unit.

3. The portable electronic device as claimed in claim 2, wherein the commands are display commands, the central processing unit transmits the display commands to the projecting module for display.

4. The portable electronic device as claimed in claim 2, further including a speaker module electronically connected to the central processing unit, wherein the central processing unit also transforms the digital signals to corresponding audio commands and the central processing unit transmits the audio commands to the speaker module for play.

5. A method of inputting information, comprising:
providing a central processing unit;
providing a projecting module;
connecting the projecting module to the central processing unit;
providing a virtual keypad projection module;
projecting a virtual keypad using the virtual keypad projection module;
providing an infrared radiation generator;
irradiating infrared light substantially parallel with the virtual keypad using the infrared radiation generator;
touching the virtual keypad with fingers and reflecting infrared light to the infrared sensor module for the infrared sensor module to generate corresponding electric signals;
sending the electric signals to the central processing unit for the central processing unit to produce commands corresponding to the pressed key of the virtual keypad;
transmitting the commands to the projecting module for the projecting module to display.

6. The method of inputting information as claimed in claim 5, further comprising the following steps:
changing the electric signals into digital signals using the infrared sensor module;
transmitting the digital signals to the central processing unit using the infrared sensor module.

7. A method of inputting information, comprising the following steps:
providing a central processing unit;
providing a speaker module;
connecting the speaker module to the central processing unit;
providing a virtual keypad projection module;
projecting a virtual keypad using the virtual keypad projection module;
providing an infrared radiation generator;
irradiating infrared light substantially parallel with the virtual keypad using the infrared radiation generator;
touching the virtual keypad with fingers and reflecting infrared light to the infrared sensor module for the infrared sensor module to generate corresponding signals;
sending the signals to the central processing unit for the central processing unit to produce commands corresponding to the pressed key of the virtual keypads;
transmitting the commands to the speaker module for the speaker module to play.

8. The method of inputting information as claimed in claim 7, further comprising the following steps:
changing the electric signals into digital signals using the infrared sensor module;
transmitting the digital signals to the central processing unit using the infrared sensor module.
